(19) United States
(12) Patent Application Publication
(10) Pub. No.: US 2013/0161702 A1
(43) Pub. Date: Jun. 27, 2013

(54) INTEGRATED MEMS DEVICE

(71) Applicant: Kun-Lung Chen, Hsinchu (TW)

(72) Inventor: Kun-Lung Chen, Hsinchu (TW)

(21) Appl. No.: 13/337,150

(22) Filed: Dec. 25, 2011

(51) Int. Cl. H01L 27/20

(52) U.S. Cl. 257/254; 257/E27.006

(57) ABSTRACT

An integrated MEMS device is provided, including, from bottom up, a bonding wafer layer, a bonding layer, an aluminum layer, a CMOS substrate layer defining a large back chamber area (LBCA), a small back chamber area (SBCA) and a sound damping path (SDP), a set of CMOS wells, a field oxide (FOX) layer, a set of CMOS transistor sources/drains, a first polysilicon layer forming CMOS transistor gates, a second polysilicon layer, said CMOS wells, said CMOS transistor sources/drains and said CMOS gates forming CMOS transistors, an oxide layer embedded with a plurality of metal layers interleaved with a plurality of via hole layers, and a gap control layer, an oxide layer, a first Nitride deposition layer, a metal deposition layer, a second Nitride deposition layer, an under bump metal (UBM) layer made of preferably Al/NiV/Cu and a plurality of solder spheres.

### FIELD OF THE INVENTION

The present invention generally relates to an integrated MEMS device, and more specifically to an integrated MEMS device built with CMOS process, Flip Chip package and wafer bonding technology.

### BACKGROUND OF THE INVENTION

MEMS devices have long been attracting attentions due to a wide range of portable applications. For example, MEMS microphone has recently gained attraction due to the use of portable devices such as smart phones, tablet and notebook computers. Also, widely used are in the devices which require noise cancellation due to the MEMS microphone device-device uniformity. However, most of the MEMS microphone was made with separate MEMS sensors and ASIC circuits with the final products assembled by wire bonding on top of a PCB substrate. Some MEMS microphones were made with single chip without wire bonding using top metal film as MEMS diaphragms.

FIG. 1 shows a schematic view of a conventional structure of a MEMS microphone with two-chip structure. As shown in FIG. 1, a two-chip structure of a MEMS microphone includes a printed circuit board (PCB) 101 used as a base, a plurality of pads 102, a CMOS circuit 103, an epoxy 104 covering CMOS 103, a MEM circuit 105, a wall 106 for encompassing the entire structure, a diaphragm 107, a back plate 108, a plurality of wire bonds 109, a lid 110 and a sound hole 111 for the sound to pass through. As shown in FIG. 1, a conventional two-chip MEMS microphone requires wire bonding and complex packaging, such as, a wall, a lid as well as a sound hole in the lid.

The problem with the two-chip solutions using wire bonding is that the wire is basically an inductive antenna and can pickup high frequency noise whose harmonics at low frequency band interferes with the sound in its frequency range. The problem with the above mentioned single-chip with metal composite film as diaphragm is long term reliability concern due to film instability when gone through temperature cycles. The other drawbacks of the above methods are high cost due to packaging. Thus, it is imperative to devise a MEMS microphone having high reliability and at the same time having low cost.

### SUMMARY OF THE INVENTION

The primary object of the present invention is to provide an integrated MEMS device by using flip-chip wafer level package and wafer bonding technology.

Another object of the present invention is to provide a MEMS microphone having high reliability and low manufacturing cost.

Yet another object of the present invention is to provide a MEMS pressure sensor having high reliability and low manufacturing cost.

An exemplary embodiment of the present invention provides a MEMS device, with WLP (Wafer Level Package) capability. A top plate of a MEMS device is made from a Nitride/Metal/Nitride sandwich used in a Flip Chip bumping technology. A back-chamber of a MEMS microphone is formed with the wafer bonding technology to bond together a CMOS MEMS wafer and a blanked Silicon wafer. A transistor gate poly silicon, a capacitor Poly Silicon-Insulator-Poly Silicon (PIP), or a combination of transistor gate poly silicon with addition of a 2^{nd} poly silicon without the insulator in the PIP capacitor module are used as MEMS microphone diaphragm when the MEMS device is fabricated to be a MEMS microphone. Also, in case of a MEMS microphone, a sound damping path is provided to create damping effects on sound wave passing through diaphragm slots. A large back chamber is included to increase the sensitivity and a portion of large back chamber area is underneath the CMOS active transistor area. The area between large back chamber areas of adjacent dies across CMOS scribe line is used for wafer-wafer bonding to seal the back chamber.

More specifically, from the bottom up, the structure of an integrated MEMS microphone of the present invention includes a bonding wafer layer made of silicon and preferably heavily doped silicon, a bonding layer made of conductive resins, Germanium, BCB or metal Au compound for wafer adhesive or eutectic bonding, an aluminum layer, a CMOS substrate layer defining, from the bottom up, a large back chamber area (LBCA), a small back chamber area (SBCA) and a sound damping path (SDP), a first set of implant doped silicon areas forming CMOS wells, a field oxide (FOX) layer made of SiO₂ oxide, a second set of implant doped silicon areas forming CMOS transistor sources/drains, a first polysilicon layer, which some areas of the first polysilicon layer forming CMOS transistor gates, a second polysilicon layer, said first polysilicon layer and said second polysilicon layer forming a bottom plate, said CMOS wells, said CMOS transistor sources/drains and said CMOS gates forming CMOS transistors, an oxide layer made of SiO2 oxide embedded with a plurality of metal layers interleaved with a plurality of via hole layers, and a gap control layer, where a first via hole layer also acting as a bottom plate contact to contact said bottom plate and said gap control layer also acting as an etch stop layer to form a MEMS area above, an oxide layer, a first Nitride deposition layer, a metal deposition layer, a second Nitride deposition layer, said first Nitride deposition layer said metal deposition layer and said second Nitride deposition layer forming a top plate, wherein said metal deposition also layer acting as top plate contact and MEMS metal contact to contact said top plate and MEMS metal layer (that is, a first metal layer of said plurality of embedded metal layers), respectively, said top plate having a dimple and a plurality of optional openings, an under bump metal (UBM) layer made of preferably Al/NiV/Cu and a plurality of solder spheres made of Sn, said UBM layer and said solder spheres forming a flip chip bump layer.

It is worth noting that the aforementioned MEMS device can be fabricated to for different functional purpose with minor alteration. For example, in case of fabricating a MEMS microphone, the aforementioned bottom plate formed by said first polysilicon layer and said second polysilicon layer must include holes. However, to fabricate the MEMS device as a MEMS pressure sensor, the aforementioned bottom plate will not include any holes.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

The present invention can be understood in more detail by reading the subsequent detailed description in conjunction with the examples and references made to the accompanying drawings, wherein:

FIG. 1 shows a schematic view of a conventional structure of a MEMS microphone with two-chip structure;

FIG. 2 shows a cross-sectional view of an integrated MEMS microphone with a single chip according to the present invention;

FIGS. 3A-3ZB shows schematic views of an exemplary embodiment of a manufacturing process to fabricate the structure of integrated MEMS microphone of the present invention;

FIG. 4 shows a schematic view of a pressure sensor as a derivative embodiment of the MEMS microphone structure of the present invention;

FIG. 5 shows a top view of the silicon MEMS microphone of the present invention;

FIG. 6 shows a cross-sectional view of the structure illustrated in FIG. 5;

FIG. 7 shows a schematic view of an embodiment with bottom sound hole configuration where a MEMS microphone in FIG. 3ZA is placed onto a PCB; and

FIG. 8 shows a schematic view of an embodiment with top sound hole configuration where a MEMS microphone in FIG. 3ZB is placed onto a PCB.

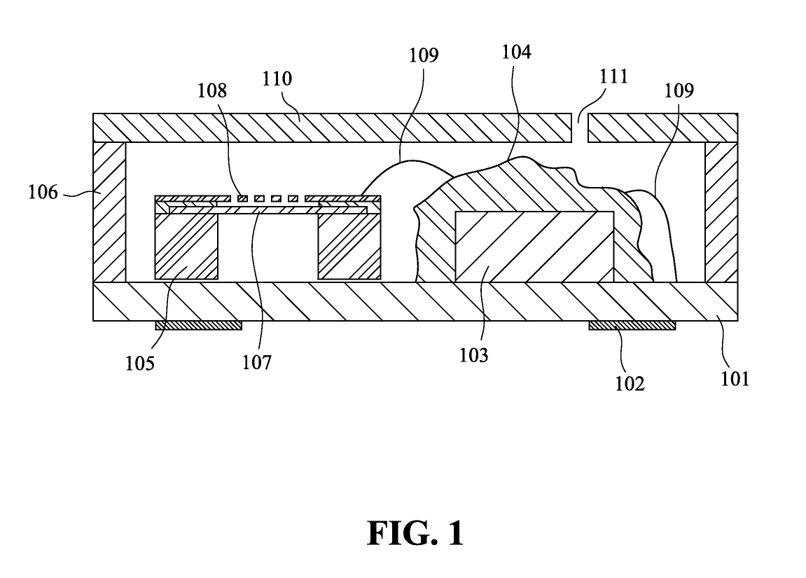

### DETAILED DESCRIPTION OF THE PREFERRED EMBODIMENTS

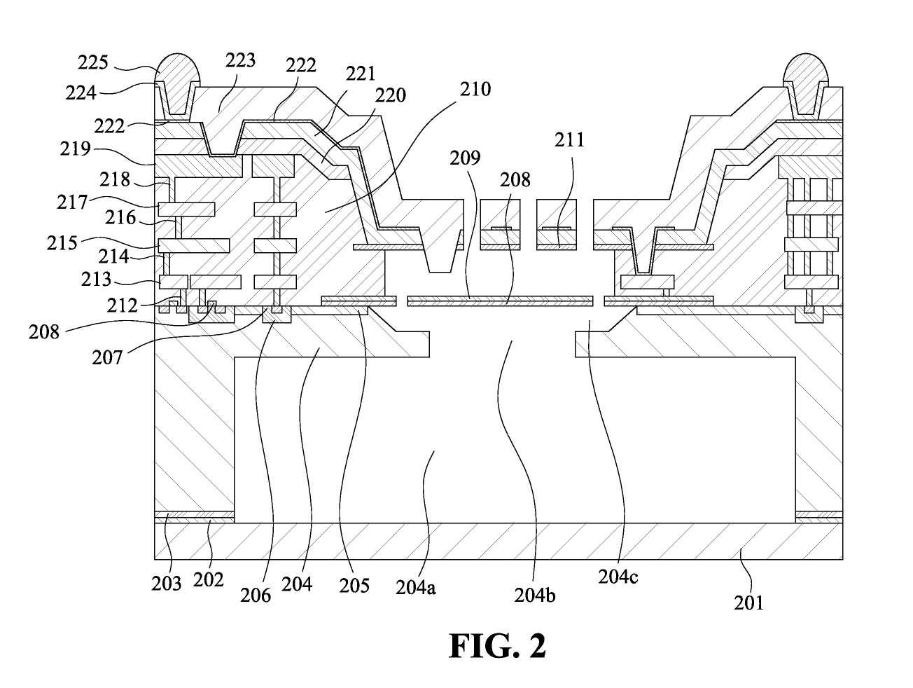

FIG. 2 shows a cross-sectional view of an exemplary embodiment of a MEMS device having a single chip structure fabricated to function as a MEMS microphone according to the present invention. As shown in FIG. 2, the integrated MEMS microphone of the present invention combines ASIC and MEMS and uses flip chip package and wafer bonding technology to fabricate. From the bottom up, the structure of an integrated MEMS microphone of the present invention includes a bonding wafer layer 201, a bonding layer 202, an aluminum layer 203, a CMOS substrate layer 204 defining, from the bottom up, a large back chamber area (LBCA) 204a, a small back chamber area (SBCA) 204b and a sound damping path (SDP) 204c, a field oxide (FOX) layer 205, a first set of implant doped silicon areas 206, a second set of implant doped silicon areas 207, a first polysilicon layer 208, a second polysilicon layer 209, said first polysilicon layer 208 and said second polysilicon layer 209 forming a bottom plate, an oxide layer 210 embedded with a plurality of metal layers interleaved with a plurality of via hole layers, and a gap control layer, where this exemplary embodiments shows four metals and four via hole layers, including a first via hole layer 212, a first metal layer 213, a second via hole layer 214, a second metal layer 215, a third via hole layer 216, a third metal layer 217, a fourth via hole layer 218, a fourth metal layer 219, first via hole layer 212 also acting as a bottom plate contact to contact said bottom plate and said gap control layer 211 also acting as an etch stop layer to form a MEMS area above, an oxide layer 220, a first Nitride deposition layer 221, a metal deposition layer 222, a second Nitride deposition layer 223, said first Nitride deposition layer 221, said metal deposition layer 222 and said second Nitride deposition layer 223 forming a top plate, wherein said metal deposition also layer acting as top plate contact and MEMS metal contact to contact said top plate and MEMS metal layer (that is, first metal layer 213 in this embodiment) respectively, said top plate having a dimple and a plurality of optional openings, an under bump metal (UBM) layer 224 and a plurality of solder spheres 225, said UBM layer 224 and said solder spheres 225 forming a flip chip bump layer.

For each layer, a plurality of preferred materials can be used. The following description is only for illustrative purpose, not restrictive. Equivalent materials can also be used to substitute. For example, bonding wafer layer 201 can be made of silicon and preferably heavily doped silicon, and bonding layer 202 can be made of conductive resins, Germanium, BCB or metal Au compound for wafer adhesive or eutectic bonding. First set of implant doped silicon areas 206 forms CMOS wells, and second set of implant doped silicon areas 207 forms CMOS transistor sources/drains. Some areas of the first polysilicon layer form CMOS transistor gates, and said CMOS wells, said CMOS transistor sources/drains and said CMOS gates form CMOS transistors. First via hole layer 212, second via hole layer 214, third via hole layer 216 and fourth via hole layer 218 are preferably made of, such as, Ti/TiN/CVD-W. First metal layer 213, second metal layer 215, third metal layer 217 and fourth metal layer 219 are made of CMOS metals such as TiN/Cu/TiN, TiN/AlSi/TiN. First via hole layer 212, second via hole layer 214, third via hole layer 216 and fourth via hole layer 218, first metal layer 213, second metal layer 215, third metal layer 217 and fourth metal layer 219 collectively form a scribe seal. First metal layer 213 is also the so-called MEMS metal layer. First Nitride deposition layer 221 can be made of Si₃N₄ silicon Nitride, metal deposition layer 222 is preferably TiN/Al/TiN, and second Nitride deposition layer 223 can be made of the same material as first Nitride deposition layer 221. UBM layer 224 is preferably Al/NiV/Cu.

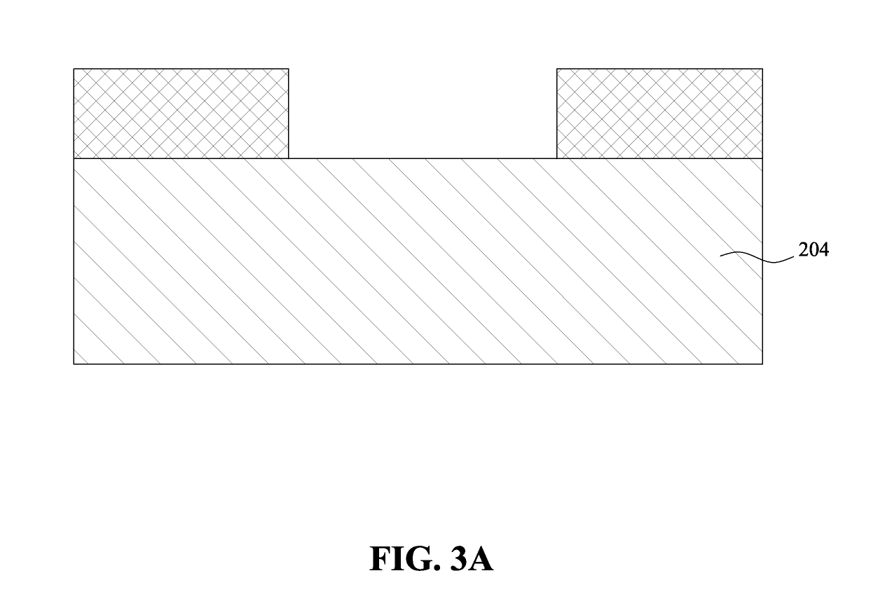

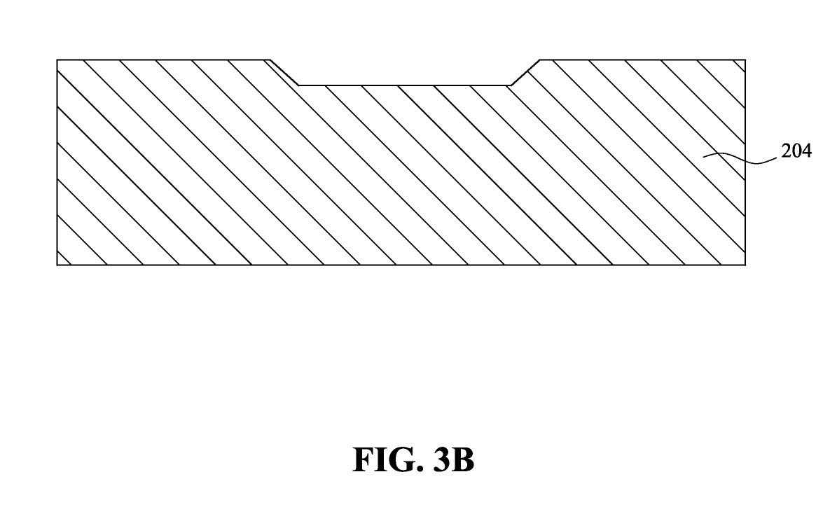

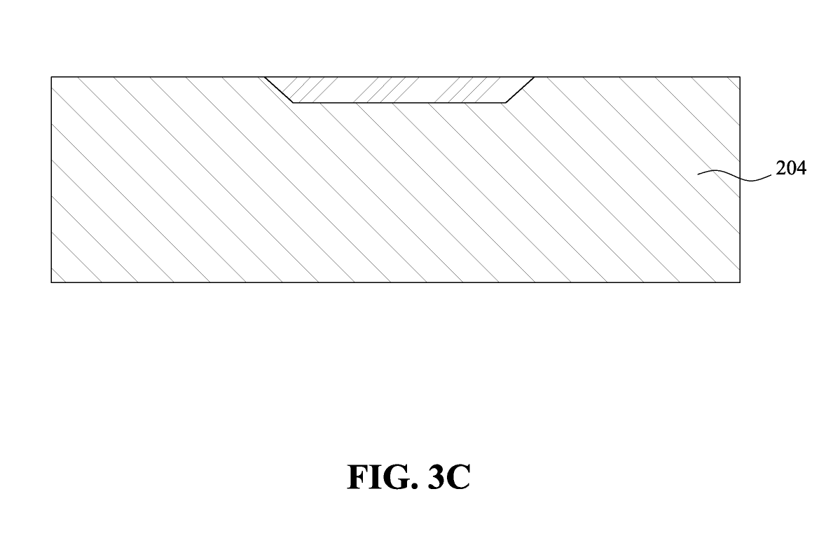

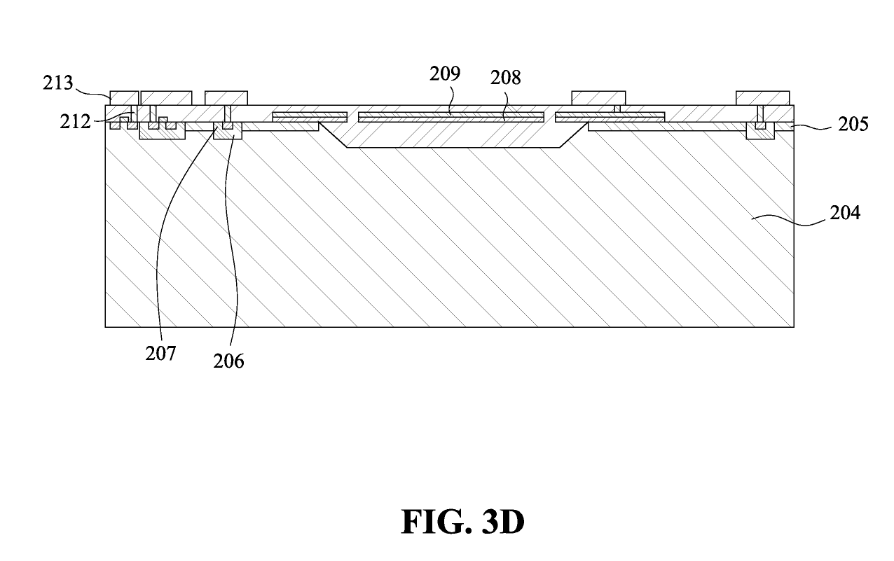

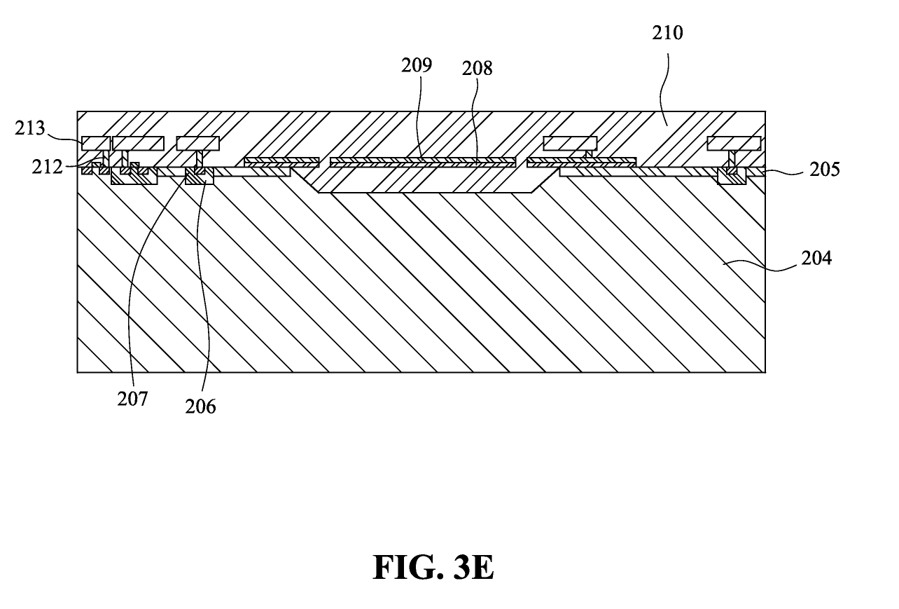

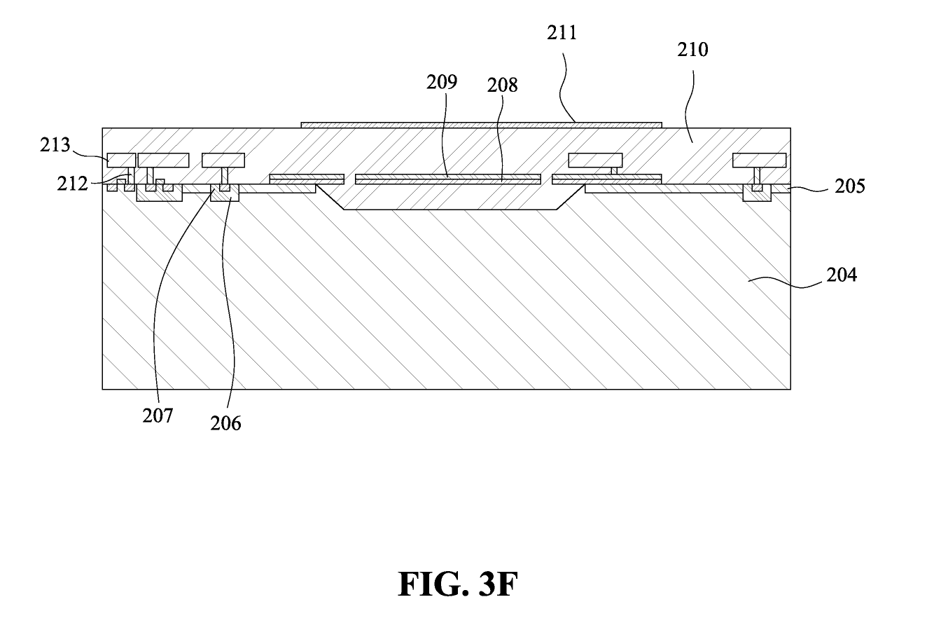

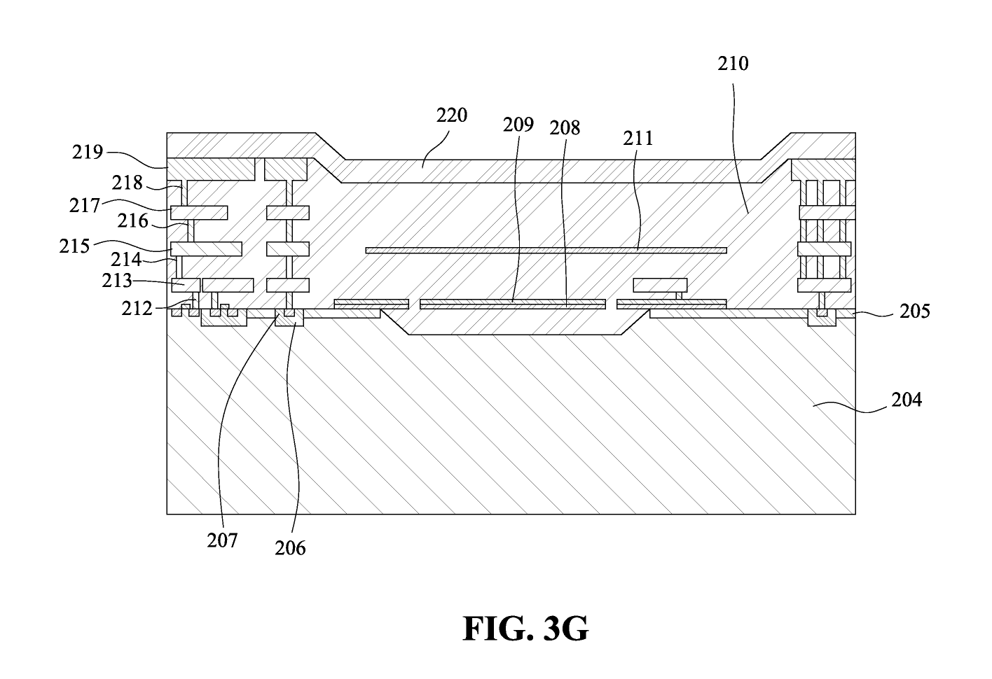

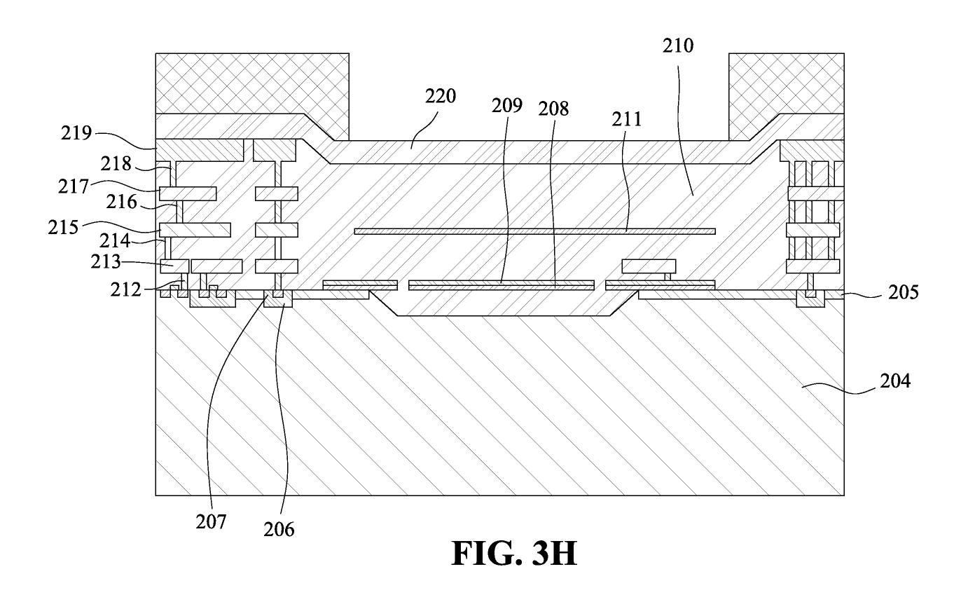

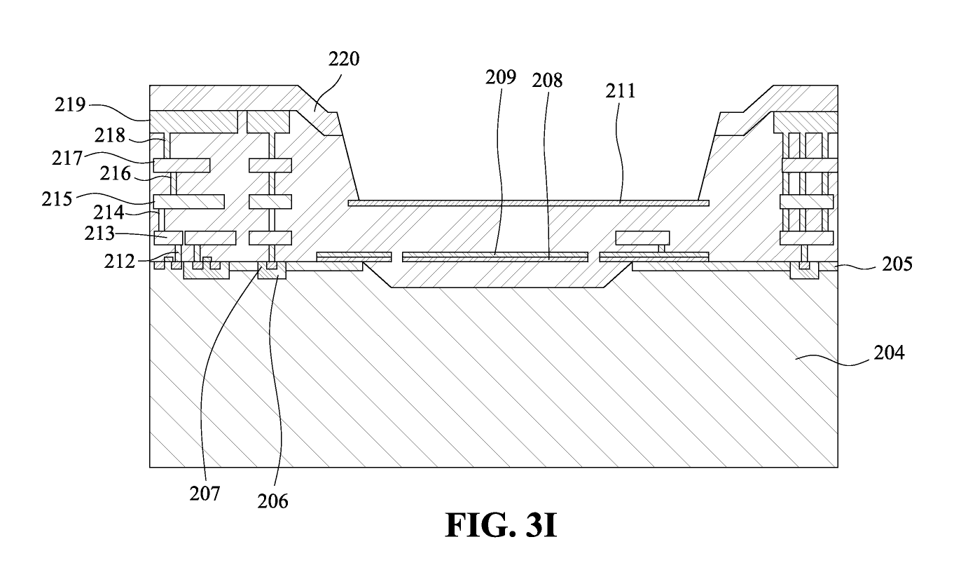

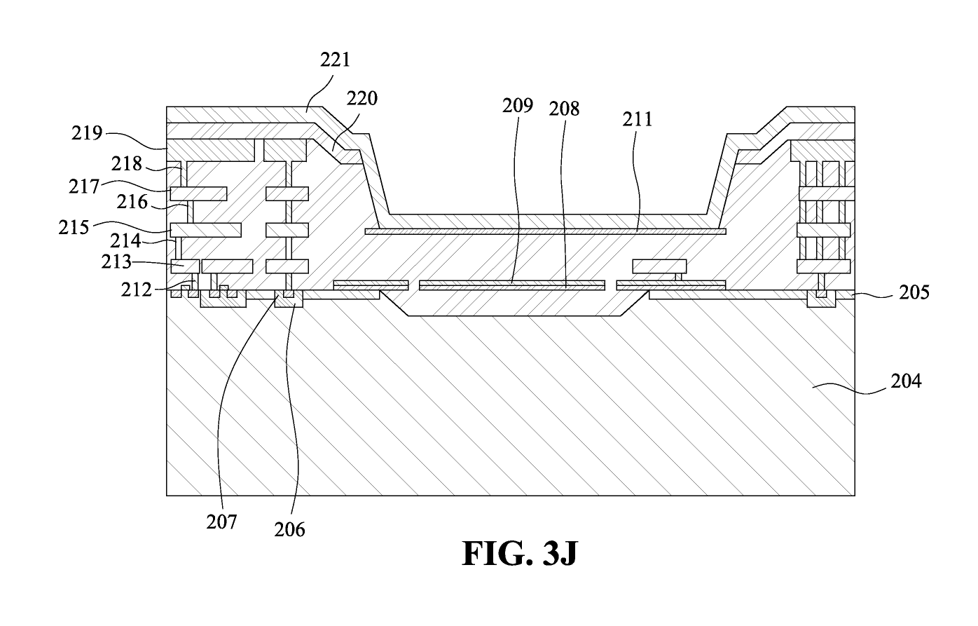

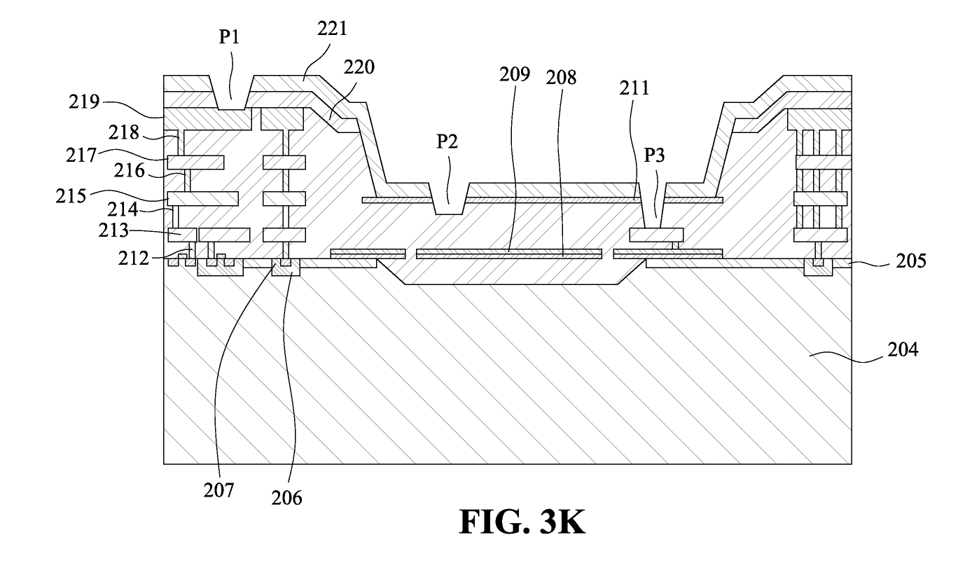

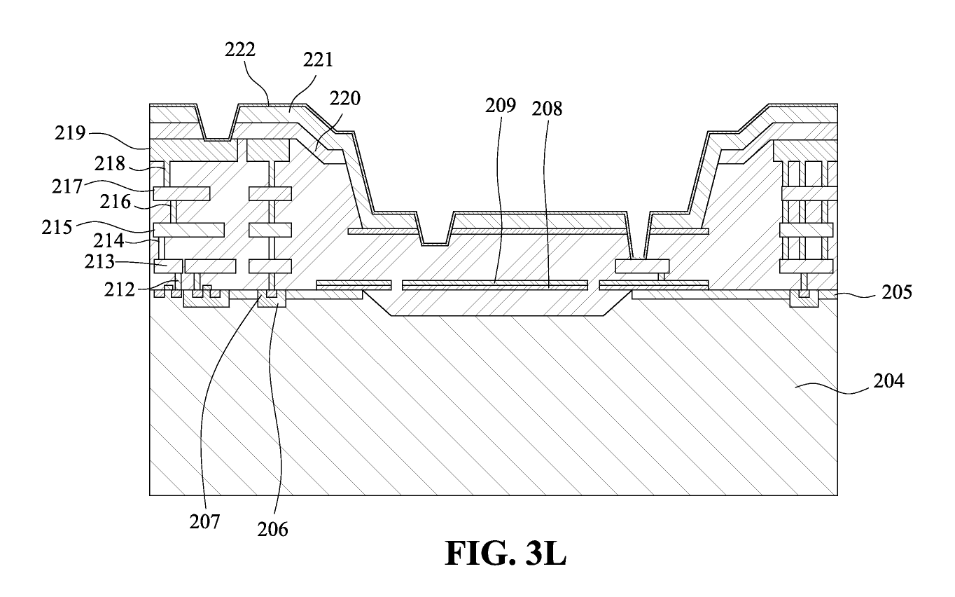

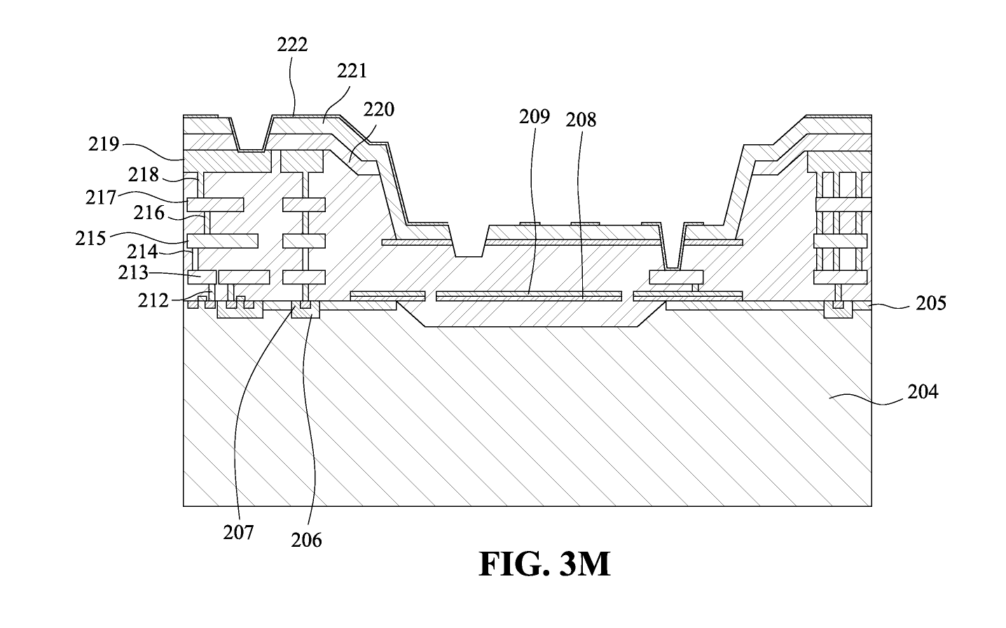

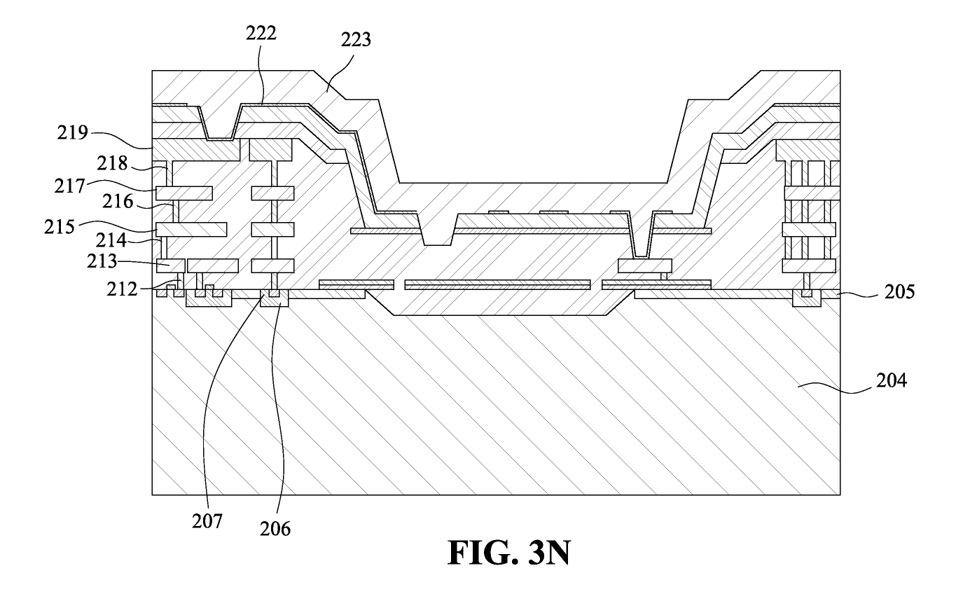

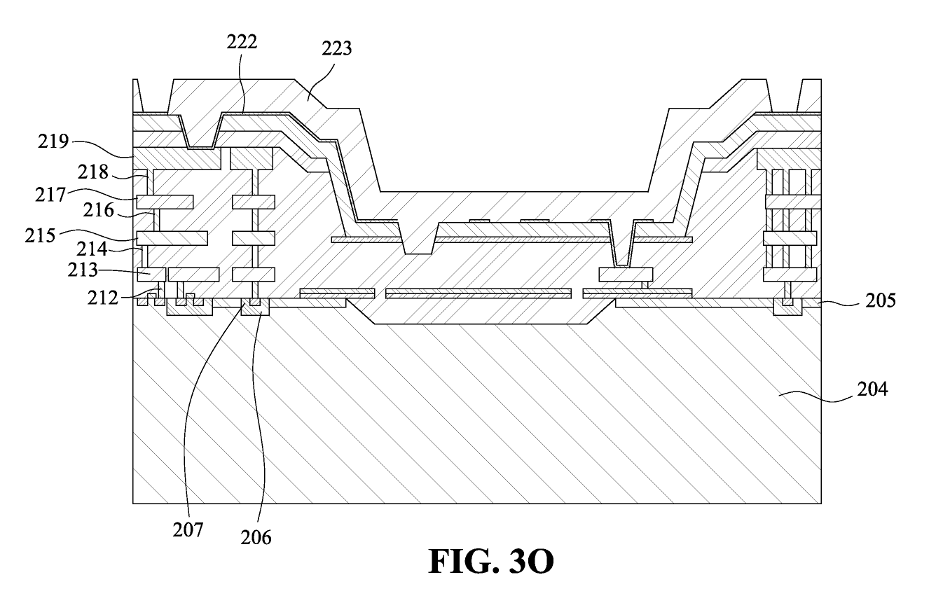

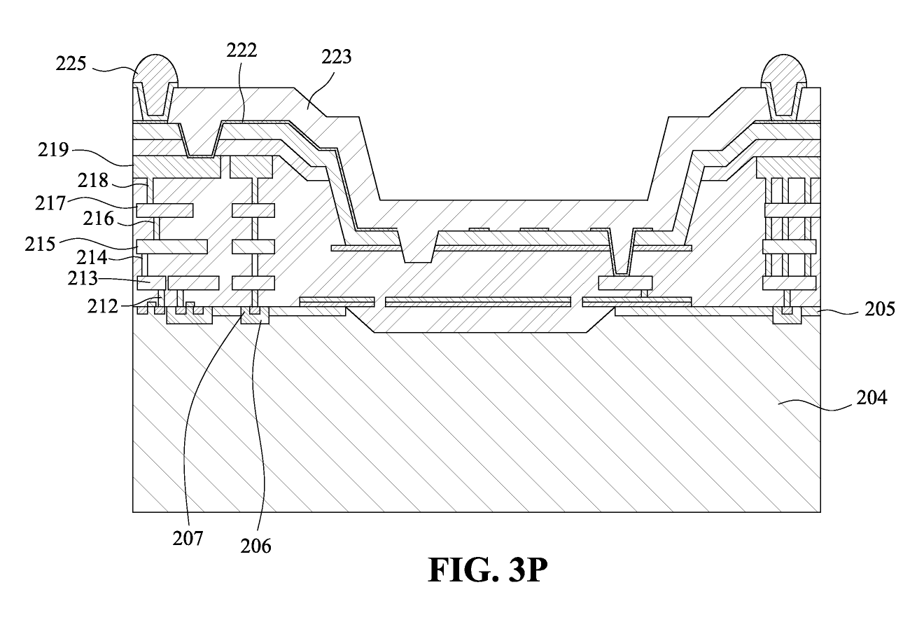

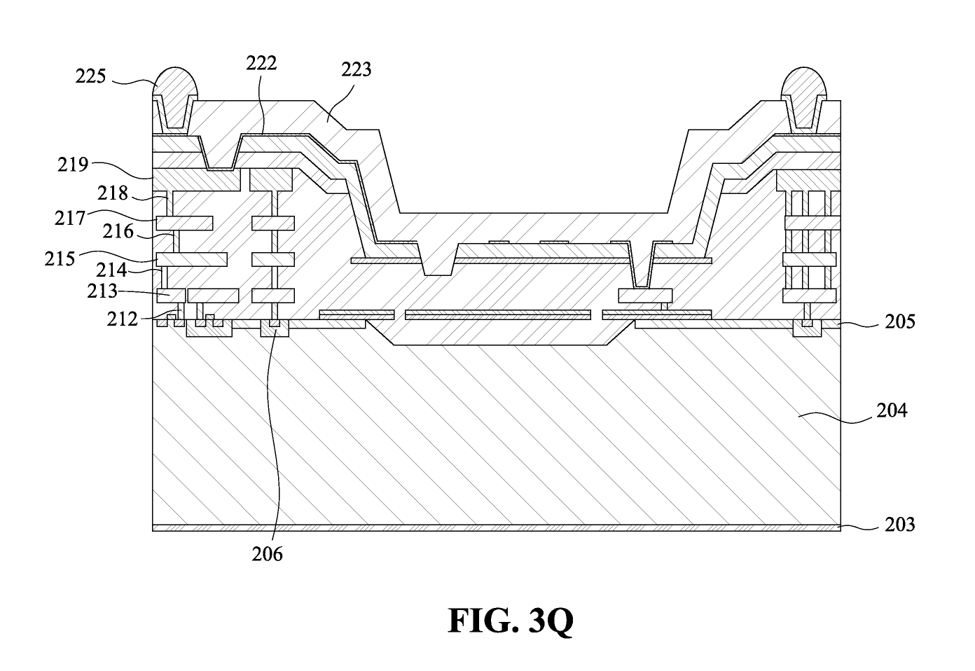

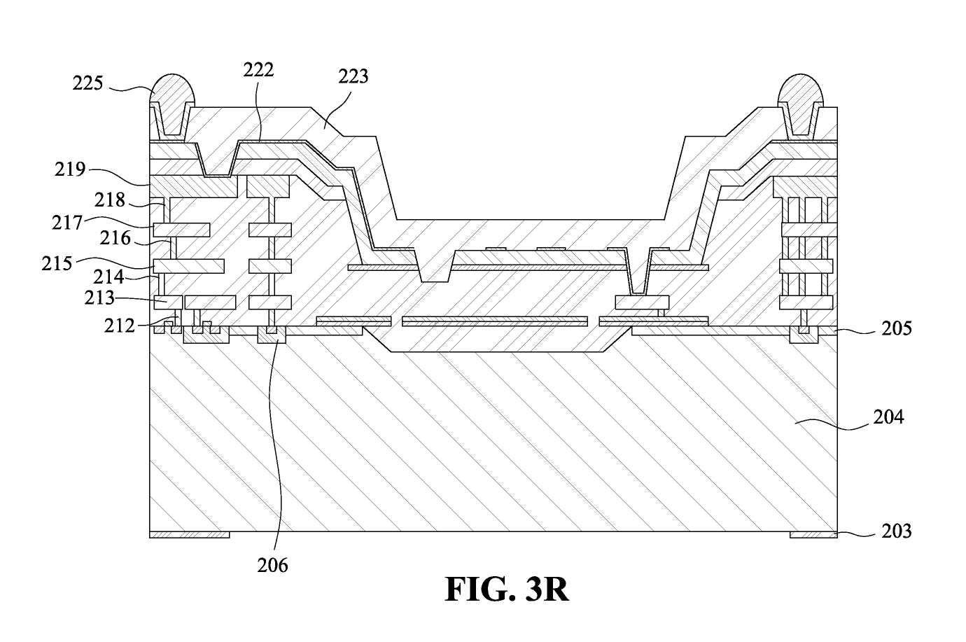

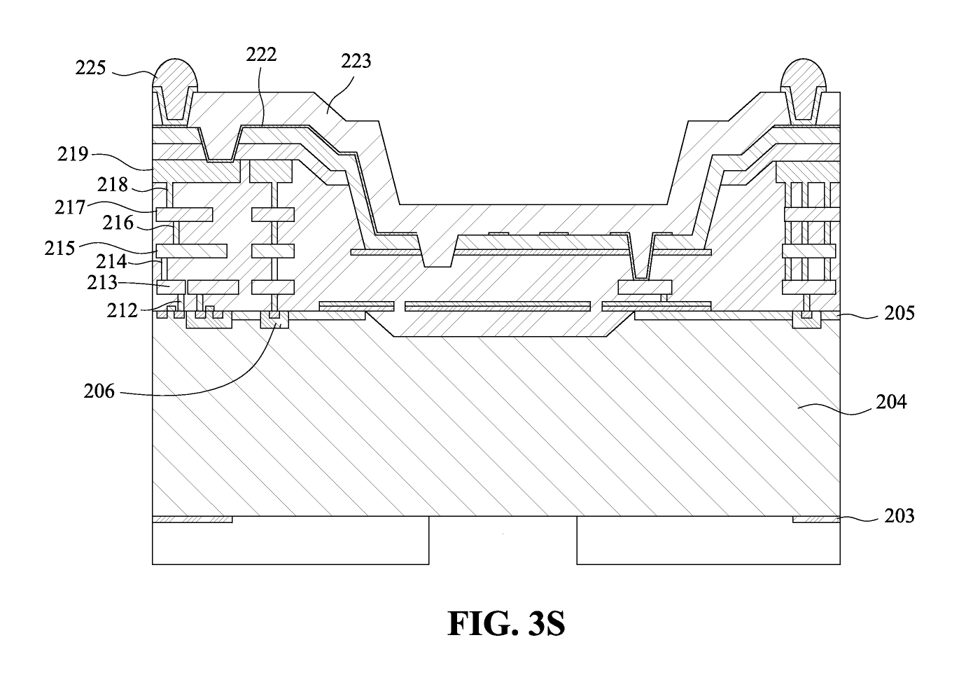

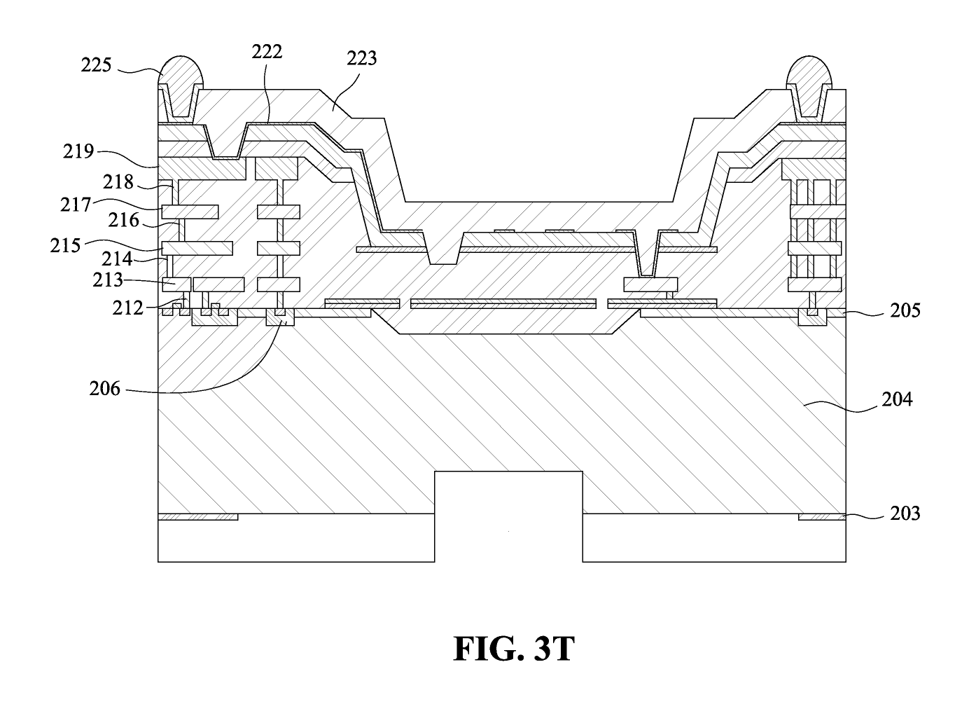

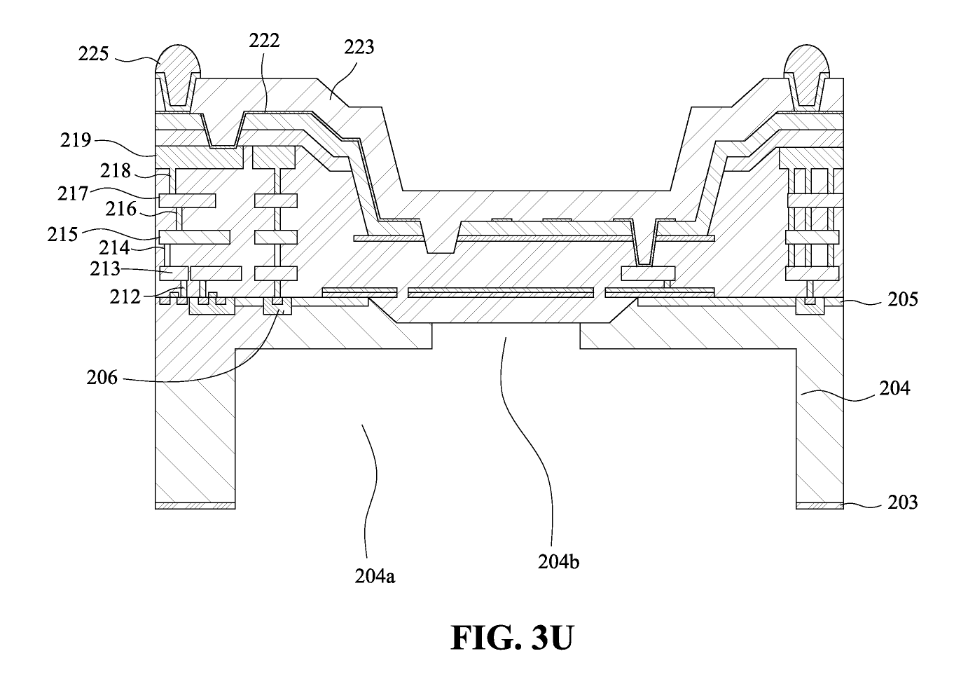

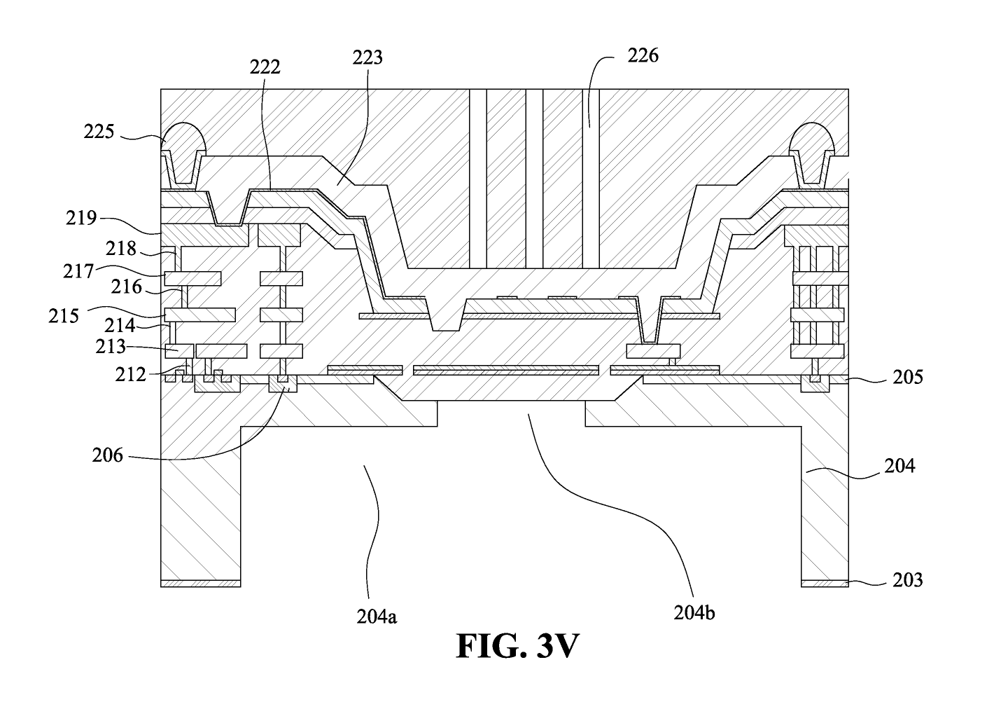

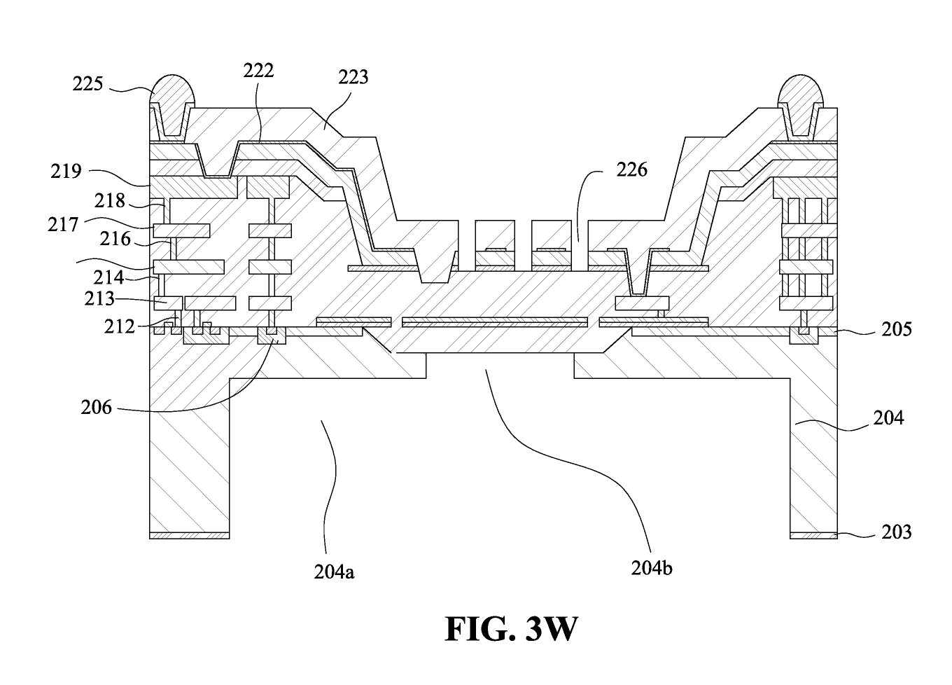

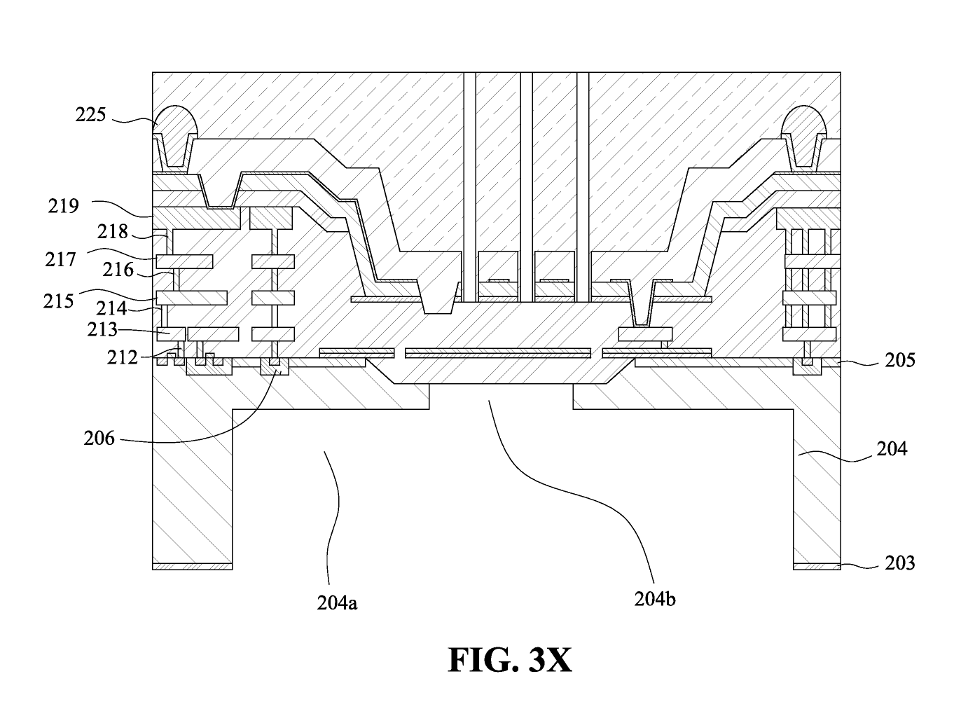

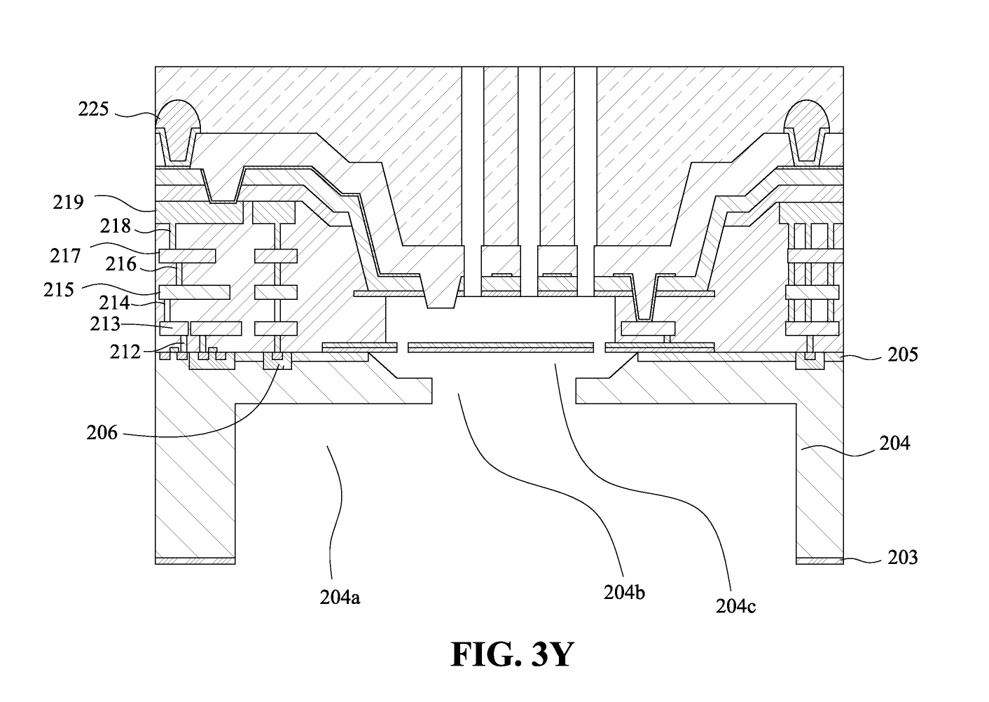

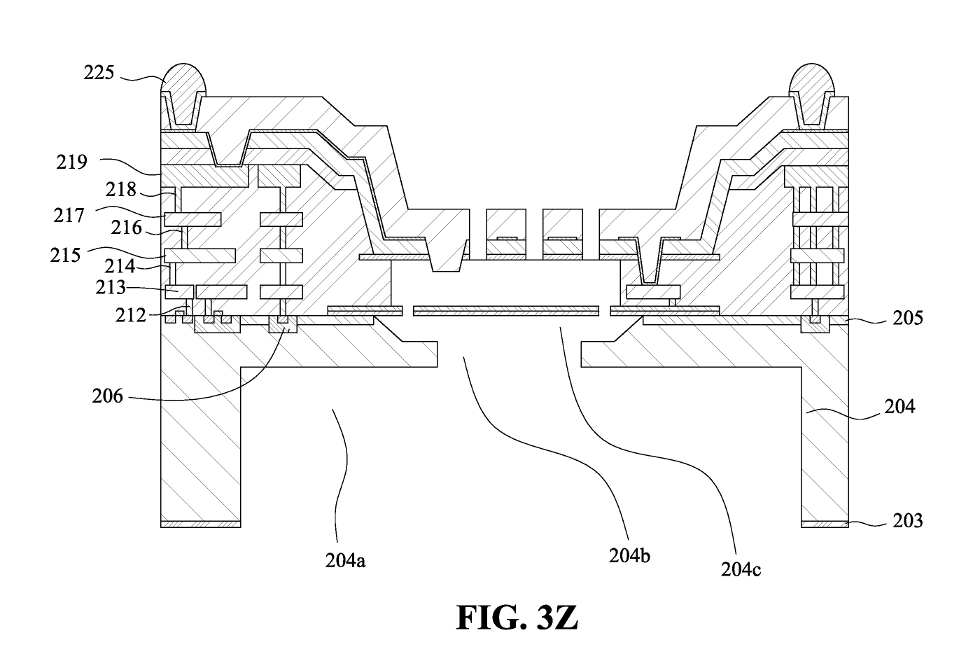

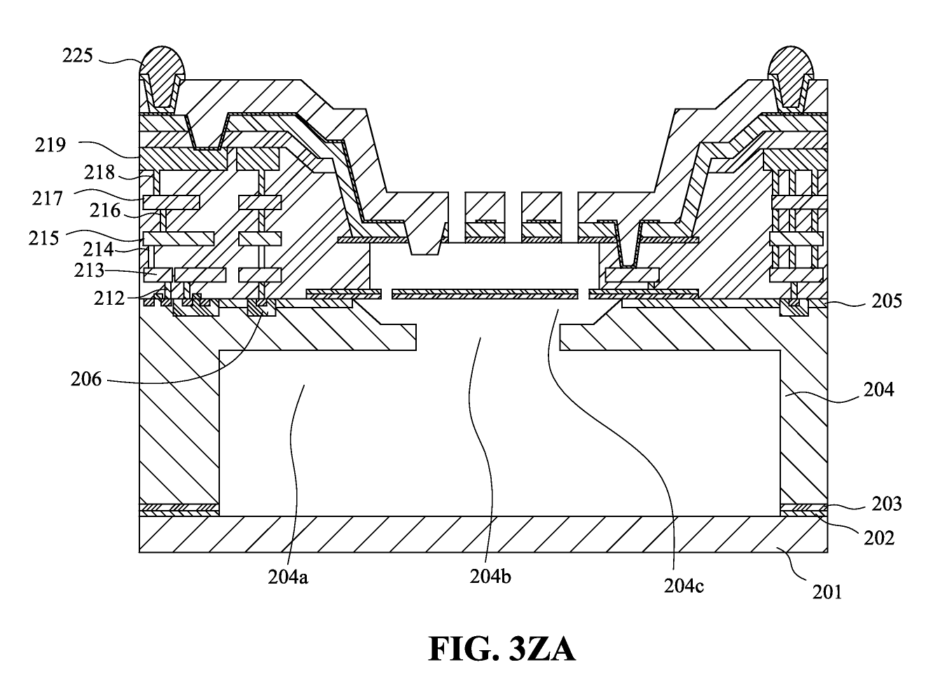

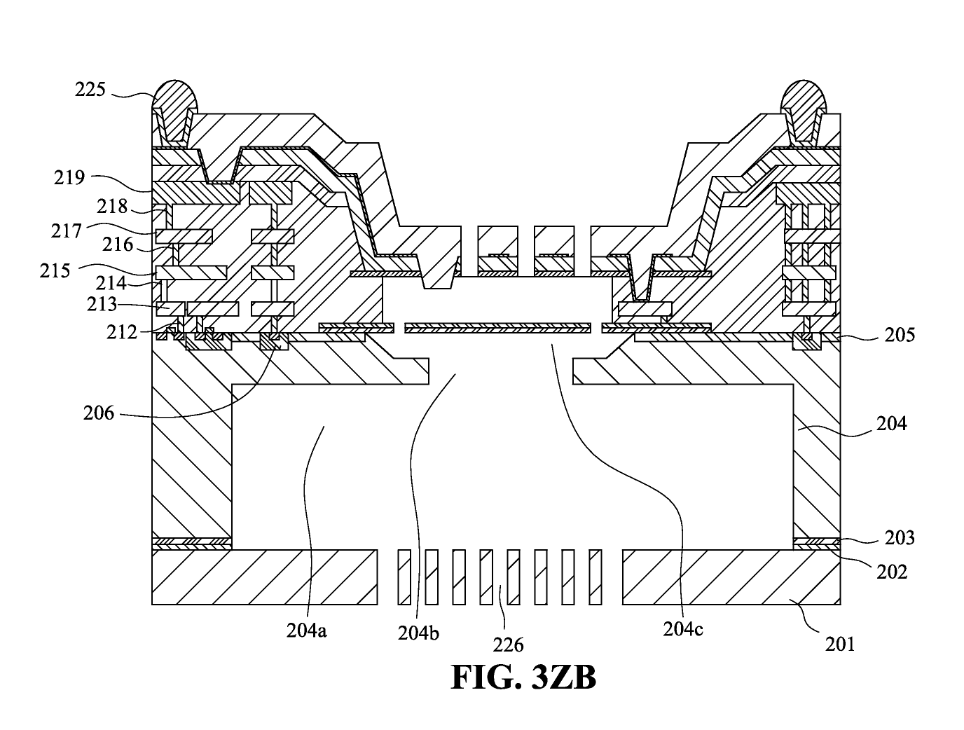

It is also worth noting while the aforementioned structure in FIG. 2 is described from the bottom up, the process to manufacture such a structure may not be from the bottom up as Flip Chip package technology is used in the preset invention. FIGS. 3A-3ZB shows schematic views of an embodiment of a manufacturing process able to fabricate the structure of integrated MEMS microphone of the present invention. However, the process and constituting steps shown in FIGS. 3A-3ZB are only illustrative, instead of restrictive. Integrated MEMS microphones manufactured in other processes are also within the scope of the structure of integrated MEMS microphone of the present invention.

FIG. 3A shows a blank silicon wafer with a photo resist pattern for the MEMS recessed silicon area definition. FIG. 3B shows the silicon blank wafer with silicon etch in the MEMS area. The recessed silicon area is then deposited and filled with LPCVD oxide and then Chemical Mechanical Polish (CMP) to planarize the surface as shown in FIG. 3C. This silicon recessed area is to create a long travel path for sound wave and thus to create damping effect for the sound passing through the diaphragm slots, that is, sound damping path, (SDP) 204c, which will be more clear in later description. FIG. 3D shows a schematic view of forming a CMOS circuit layer with transistor formation and process up to first metal layer pattern and etch step. As shown in FIG. 3D, MOS layer comprising three layers 206, 207, 208 forming CMOS transistors are fabricated on substrate layer 204, and then first polysilicon layer 208, second polysilicon layer 209, first via hole layer 212, first metal layer 213 are fabricated accordingly. After first metal layer 213 definition in FIG. 3D, oxide deposition 210 is performed and Chemical Mechanical Polish (CMP) is used to planarize the surface as is shown in FIG. 3E. A thin gap control layer (Lgc) 211 is then deposited and pattern etched to define the MEMS area. This thin gap control layer is later to be used as an etch stop layer for oxide etch, a preferred embodiment of the thin layer can be either a Nitride layer or a thin metal layer. FIG. 3F shows gap control layer 211 after photo resist pattern and layer etch in MEMS area. Gap control layer 211 can be formed before or after the deposition of first metal layer 213 or in between the CMOS inter-level-oxide by adjusting the sequence or additions of the CMOS thin inter-level oxide deposition process.

FIG. 3G shows a schematic view of a CMOS wafer with pre-defined MEMS area with first polysilicon layer 208, second polysilicon layer 209 thin films and transistor gate poly. It is worth noting that transistor gate poly can be one of the stack of first polysilicon layer 208 and second polysilicon layer 209 on top of Field Oxide layer 205 (FOX). MEMS are surrounded by oxide layer 210. First polysilicon layer 208 and second polysilicon layer 209 composite films serve as the MEMS microphone diaphragm, with mechanical property of both polysilicon films adjusted to make the composite film close to zero stress for high sensitivity microphone diaphragm or to make a polysilicon gate poly as a low stress polysilicon film to meet the diaphragm characteristics. It is thus in this invention that the MEMS microphone diaphragm contains a polysilicon material that is at the same time used as CMOS transistor gates. The CMOS wafer as shown in FIG. 3G is a complete CMOS structure before Nitride Protective Overcoat (PO) deposition.

The wafer is then going through MEMS area photo resist pattern as shown in FIG. 3H to define the oxide recessed area. An Inter-Level-oxide or Multi-Layer-Oxide (MLD) 220 between metals are etched away with the gap control layer 211 as an etch stop layer, as shown in FIG. 3I. This embodiment shows four layers of metals (213, 215, 217, 219) in the CMOS process; however, as aforementioned, the number of metal layer can be determined based on the ASIC design requirements or for low manufacturing cost with minimized metal layers. If the numbers of metal layers are small, then the oxide recessed step can be eliminated as a gap between resulting stacked Nitride film and the polysilicon film are small enough for making sensitive MEMS microphone devices. The capacitance value of the MEMS microphone capacitor is determined between conductive top plate layer, that is, metal layer 222, and conductive diaphragm/bottom plate layer (208, 209), conductive polysilicon in this case. The distance between top plate layer and the conductive polysilicon diaphragm determines the capacitance value, which will generate an incremental capacitance variation under a sound pressure change, and thus an electrical signal corresponding to the sound pressure change is generated by ASIC circuits. An adequate control of the gap between capacitive electrode plates is thus necessary for a high volume production of the device. The capacitor gap is determined by the thickness of first Nitride deposition layer 221 and the thickness of gap control layer 211 and the remaining oxide thickness after etching CMOS inter-level oxide in FIG. 3I. The thickness of first Nitride deposition layer 221 and gap control layer 211 can be well controlled by the slowing down deposition rate during film deposition. An etch stop layer 211 (in other words, gap control layer 211 acting as an etch stop layer) is needed to prevent the oxide etch step from over etching and thus capacitance control is obtained. A desired gap control layer 211 can be formed before or after first metal layer deposition in order to adjust the remaining inter-level oxide thickness after etch and thus the gap control purpose of this layer is achieved.

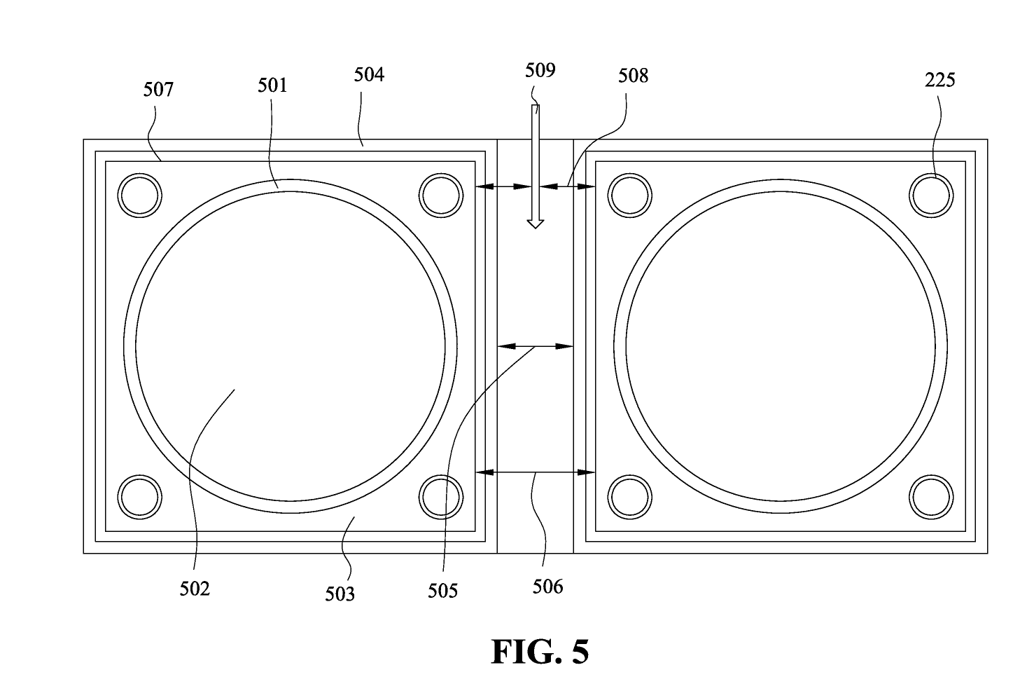

After the MEMS area recessed oxide etch, a first Nitride deposition layer 221 is deposited, as shown in FIG. 3J. The thickness of first Nitride deposition layer 221 is preferably around 7000A°. This first Nitride deposition layer 221 is used in the final film to protect the CMOS outside environment in a regular CMOS process. The process then proceeds to the Re-Distribution-Layer (RDL) back end process. Photo resist pattern and Nitride etch is performed on first Nitride deposition layer 221. This process step is to define via holes for RDL metal layer 222 to connect to the metal layer (in this case fourth metal layer 219 in the CMOS ASIC circuit area and first metal layer 213 in the MEMS area), in other words, the aforementioned top plate contacts and bottom plate contacts, respectively. Separate additional masks can be used for the RDL vias to first metal layer 213 if the oxide thickness difference during RDL via etch for fourth metal layer 219 and first metal layer 213 creates problem in the process. During the first Nitride deposition layer 221 pattern definition and etch step, a dimple pattern and etch is also performed, and thus the dimple for the MEMS microphone is formed simultaneously, as shown in FIG. 3K, a pattern P1 for top plate contacts (defined as TpC) to top metal (fourth metal layer 219), a pattern P2 for dimple and a pattern P3 for a MEMS contact (defined as MmC) to first metal layer 213 which is then connected to the bottom plate by the first via hole (defined as BpC) layer 212. The wafer is then going through metal deposition for the RDL layer 222 interconnect layer, the metal composition is preferably layer composition of TiN/Aluminum/TiN as shown in FIG. 3L. Then, a photo resist pattern to define the RDL interconnect layer and at the same time to define the MEMS top plate and bottom plate interconnects are shown in FIG. 3M with patterned metal etched and photo resist stripped. The process proceeds with second Nitride deposition layer 223 as shown in FIG. 3N, then followed by the photo resist pattern and related second Nitride deposition layer 223 etch to form holes for flip-chip bumping process as shown in FIG. 3O. Under bump metal (UBM) layer 224 and flip chip solder bumps 225 are then formed on top of the silicon as shown in FIG. 3P. At this step, all interconnect layers to connect the MEMS electrical terminals to the ASIC circuits are completed. The top plate conductive layer 222 goes along with first Nitride deposition layer 221 entering ASIC circuit area from the chip top surface, and then landed on the top metal of the ASIC chip, that is, fourth metal layer 219 in this embodiment. Fourth metal layer 219 is then connected to CMOS transistors as an input to the ASIC circuits through aforementioned top plate contact (TpC). The bottom plate is made of poly silicon and its contact to metall is made through aforementioned bottom plate contact (BpC). Since the bottom plate is connected to first metal layer 213 in the MEMS area, and first metal layer 213 in the MEMS area is connected to top plate metal layer 222 through aforementioned MEMS metal Contact (MmC), aforementioned bottom plate contact (in other words, diaphragm contacts for electrical signals) can pass over the ASIC scribe seal entering into the ASIC circuit area and landed on the top metal of the ASIC circuits, the same way as aforementioned top plate contacts. The interconnects to connect the MEMS microphone terminals (top and bottom plates) to the ASIC circuits for signal processing are thus completed without disturbing the ASIC scribe seals, which are important to guarantee the CMOS ASIC circuit reliability preventing from contamination by external environmental impurity. The ASIC circuits are thus protected by two enclosed un-interrupted scribe seals, one is at the interface between MEMS elements and the ASIC circuits, the other is at the interface between ASIC circuits and its die saw scribe lines as shown in FIG. 5. The process is then switched to the backside silicon substrate bottom surface.

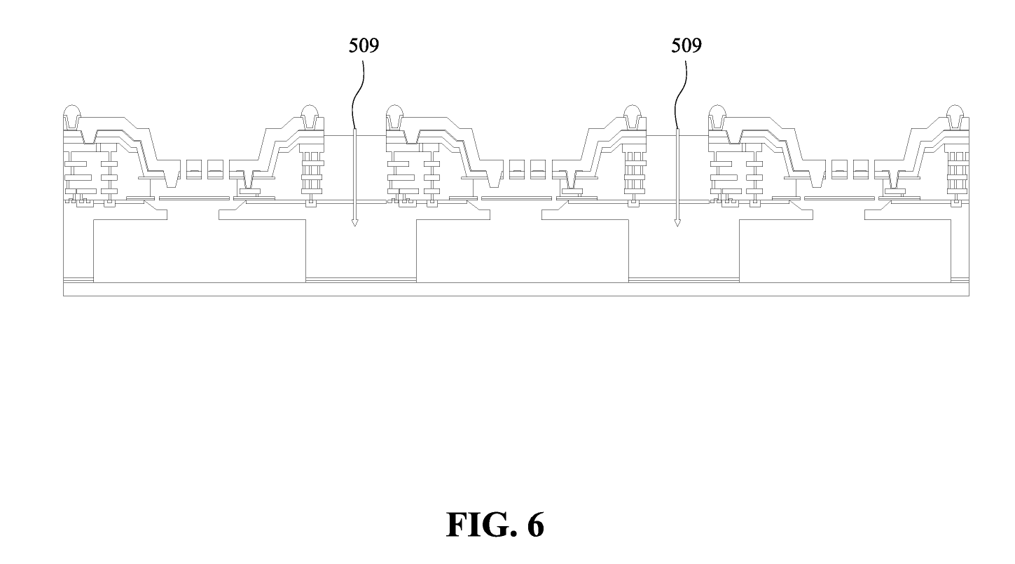

A thin layer of metal, for example, aluminum, 203 is deposited on the back side of the silicon substrate as shown in FIG. 3Q. Alternatively, Nitride or Oxide, semiconductor materials having high etch ratio to silicon can also be used during ICP silicon etch step. These materials serve as a hard mask etch stop for a subsequent small back chamber ICP etch. The photo resist pattern and etch in FIG. 3R defines a hard mask area. FIG. 3S shows a first ICP photo resist pattern. Then the ICP silicon etch step follows with etch depth of around 30-50 um to form a small area of back chamber volume, as shown in FIG. 3T. The photo resist is then stripped away. Then a second ICP silicon etch step is performed with the pre-defined hard mask. The second ICP etches through the silicon substrate until the oxide refill after silicon recess etch process in FIG. 3B in the center MEMS area is reached and a thickness of around 30-50 um of silicon remains underneath the CMOS transistor area as shown in FIG. 3U. The substrate thickness of around 30-50 um is to guarantee a proper function of CMOS transistors, as the recent CMOS technology has wafer thinning down to 30-50 um without transistor performance issues. The second ICP is to create large back chamber area (LBCA) 204a so that the MEMS microphone back chamber is not confined and limited to the small area under MEMS diaphragm. The purpose and advantage of forming a large back chamber area (LBCA) 204a is to increase the back chamber volume and thus increase the sensitivity of the MEMS microphone. LBCA 204a in this invention is made under the ASIC circuit area without affecting the ASIC performance and thus a minimized single chip size and cost are achieved with optimized performance. In order to maximize the back chamber volume, LBCA 204a is made with square shape as shown in FIG. 5 in X-Y horizontal dimension, SBCA 204b is in circular shape under diaphragm with thickness of about 30-50 um as defined earlier for CMOS transistor function requirements. The square boundary of LBCA 204a is not limited by the size of the MEMS rather by the size of the combined ASIC circuit area and the MEMS area. The depth of LBCA 204a is determined by the wafer substrate thickness. The process then switches back to top side of the wafer to define a plurality of MEMS top plate sound holes 226, a photo resist layer is shown as in FIG. 3V. Since the size of MEMS top plate sound hole 226 is large, for example, 5-30 um in diameter, the photo resist thickness can be thick without affecting the accuracy of geometry. After top side Nitride etch and resist layer stripped, the wafer with top side sound hole is shown in FIG. 3W. The wafer top is then re-patterned with a photo resist pattern with portion of photo resist inside the sound hole to protect the sidewall of the sound hole and the solder bump 225 from subsequent wet solution for MEMS oxide release as shown in FIG. 3X. After the resist pattern, the whole wafer undergoes wet solution oxide release etch to etch away the oxide in between the diaphragm and top plate of the MEMS microphone and the recessed refilled oxide, underneath the polysilicon diaphragm as shown in FIG. 3C, is also etched away. The structure after MEMS oxide wet etch release is as shown in FIG. 3Y. FIG. 3Z shows the structure after photo resist removal. Bonding layer 202 is then deposited or pasted on top of a blank flat wafer 201 with the bonding layer 202 patterned etched or pasted with utensil. The CMOS MEMS wafer is then bonded together with the blank flat wafer with wafer-wafer bonding technology. The preferred wafer-wafer bonding technology is adhesive bonding or eutectic bonding, which have low temperature process during bonding. This wafer-wafer bonding step is to seal the back chamber of the MEMS microphone. A final resulting MEMS microphone is shown in FIG. 3ZA. However, if the sound hole is on top with a created large back chamber resided in PCBs, then the MEMS microphone in FIG. 3ZB is used. The making of the MEMS microphone of FIG. 3ZB is shown below. The bonding wafer 201 for back chamber sealing is etched with the sound hole aligned to the back chamber. These sound holes are created with a photo resist pattern and silicon is etched in the bonding wafer 201. These resulting holes 226 serve as particle filters to prevent external particle in the environment from entering MEMS device. The sound pressure changes the capacitance between the diaphragm and the top plates through the induced diaphragm movement, same as in the case of bottom sound holes. The wafer bonding technique used in this invention is to seal the back chamber so that a single chip MEMS device can be manufactured in an all-semiconductor process methodology without relying on wire bonding in a conventional two-chip solution. The bonding wafer layer further forms a plurality of hole as particle filters. The wafer level package (WLP) is achieved with a combination of flip-chip bumping as shown in FIG. 3P and the wafer bonding technology as shown in FIG. 3ZA. No additional chip package steps of the MEMS device is needed in this invention. The complete wafer as shown in FIG. 3ZA will go through die saw with its individual dies ready for the final test and shipping to customers. Different wafer bonding methodologies and bonding materials can be chosen, such as adhesive bonding materials, eutectic bonding materials. For the case of eutectic bonding, a bonding metal gap is reserved in the ASIC scribe seal area so that laser die saw, as shown in FIG. 6, to separate individual chips can be done. However, in the case of adhesive bonding, no additional gap is needed for laser die saw.

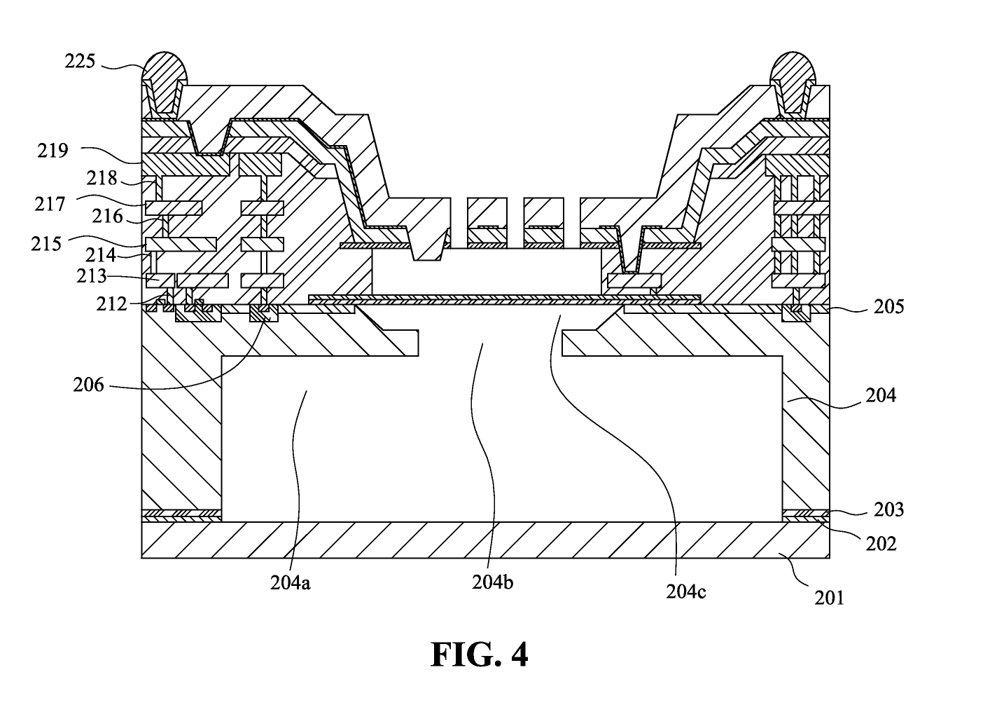

FIG. 4 shows a schematic view of another embodiment of a MEMS device functioning as a MEMS pressure sensor according to the present invention. As shown in FIG. 4, the diaphragm layer, that is, the aforementioned bottom plate layer is continuous without any holes or slots. The derivative embodiment of the present invention is an integrated single-chip capacitive pressure sensor with enclosed back chamber formed by the slot-less poly silicon diaphragm and the bonding wafer at the CMOS substrate. An increasing pressure will push the diaphragm away from the back plate and thus reduce the MEMS capacitance. The sensing ASIC circuit is designed to sense the changing capacitance and converts the pressure into an electrical signal for the pressure measurement.

FIG. 5 shows a top view of the silicon MEMS microphone. The ASIC circuit is layout around the circular diaphragm so that the overall all chip size is minimized. There is an inner ring scribe seal 501 existing at the interface of MEMS area 502 and ASIC circuit area 503 so that the ASIC circuit reliability is preserved as in the case of a conventional ASIC scribe seal, shown as an outer ring scribe seal 504 at the edge of scribe line 505. A wafer-wafer bonding area 506 is defined as area in between large back chamber (LBCA) boundary 507 of adjacent dies across ASIC outer ring scribe seal 506 and scribe line area in between the chips as shown in FIG. 5. A remaining silicon after die saw 508, which is the silicon area defined as from the edge of a die saw blade 509 to the edge of the LBCA, serves as a vertical mechanical support and served as a vertical sidewall of the sound chamber formed with the bonding wafer in the present invention. The circles at the corners indicate solder bumps 225.

FIG. 6 shows a cross-sectional view of a die saw process step through the CMOS MEMS scribe line area according to the present invention. As a result, separate integrated MEMS microphone devices are ready for soldering into a customer PCB. No wire bonding, no lead frame, no molding is required. Thus the resulting MEMS microphone size is reduced to a very minimum in size both vertically and horizontally.

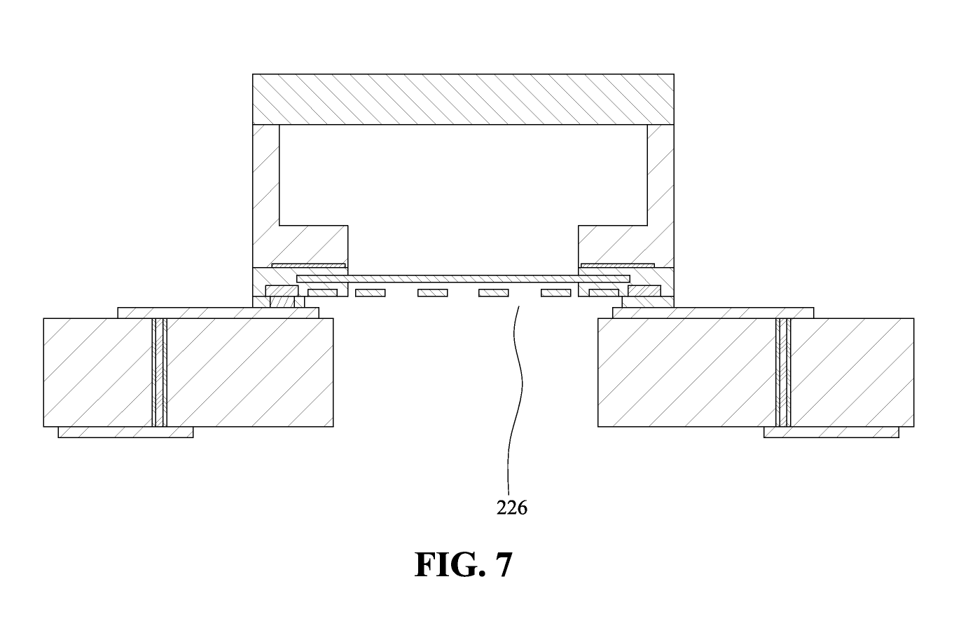

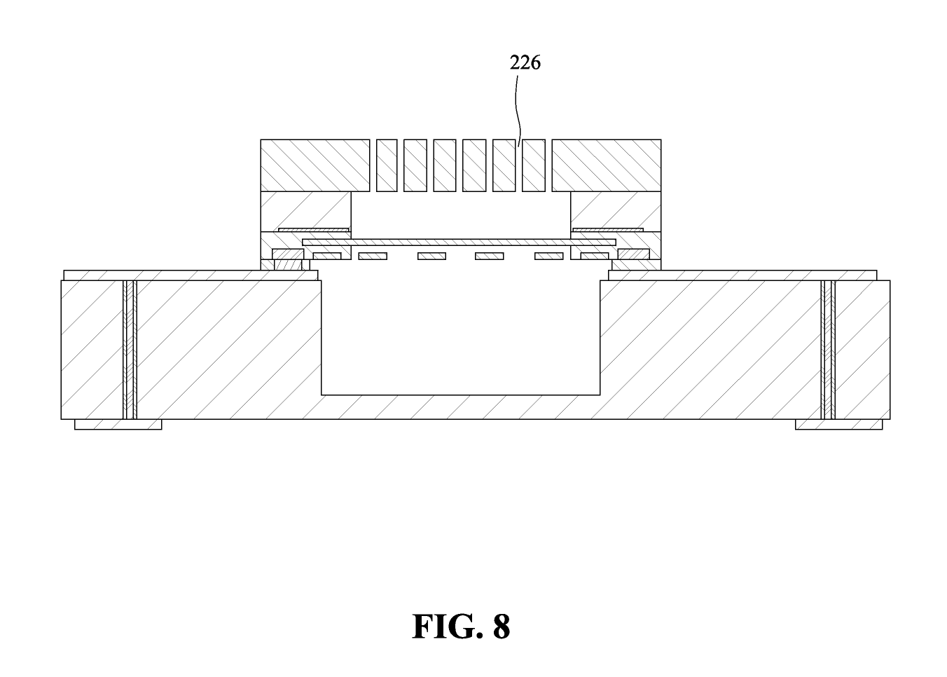

FIG. 7 shows a schematic view of a MEMS microphone with sound holes 226 at the bottom being placed onto a PCB, and FIG. 8 shows a schematic view of the embodiment with top sound holes 226 in FIG. 3ZB placed on a PCB according to the present invention.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

Claimed is:

1. An integrated MEMS device, comprising, from bottom up:
a bonding wafer layer;
a bonding layer;
an aluminum layer;
a CMOS substrate layer defining, from the bottom up, a large back chamber area (LBCA), a small back chamber area (SBCA) and a sound damping path (SDP);
a field oxide (FOX) layer;
a first set of implant doped silicon areas;
a second set of implant doped silicon areas;
a first polysilicon layer;
a second polysilicon layer, said first polysilicon layer and said second polysilicon layer forming a bottom plate;
an oxide layer embedded with a plurality of metal layers interleaved with a plurality of via hole layers, and a gap control layer, wherein a first via hole layer of said plurality of via hole layers also acting as a bottom plate contact to contact said bottom plate, said gap control layer also acting as an etch stop layer to form a MEMS area above;
an oxide layer;
a first Nitride deposition layer;
a metal deposition layer;
a second Nitride deposition layer, said first Nitride deposition layer, said metal deposition layer and said second Nitride deposition layer forming a top plate, wherein said metal deposition also layer acting as top plate contact and MEMS metal contact to contact said top plate and MEMS metal layer respectively, said MEMS metal layer being a first metal layer of said plurality of embedded metal layers, said top plate having a dimple and a plurality of optional openings;
an under bump metal (UBM) layer; and
a plurality of solder spheres, said UBM layer and said solder spheres forming a flip chip bump layer;
wherein said first set of implant doped silicon areas forming CMOS wells, said second set of implant doped silicon areas forming CMOS transistor sources/drains, some areas of said first polysilicon layer forming CMOS transistor gates, and said CMOS wells, said CMOS transistor sources/drains and said CMOS gates forming CMOS transistors, said plurality of metal layers interleaved with said plurality of via hole layers collectively forming a scribe seal.

2. The integrated MEMS device as claimed in claim 1, wherein said bottom having a plurality of slots can function as a MEMS microphone.

3. The integrated MEMS device as claimed in claim 1, said CMOS transistor gate polysilicon, said capacitor polysilicon-insulator-polysilicon (PIP), or a combination of said transistor gate poly silicon with addition of said polysilicon without said insulator in said PIP capacitor module are used as MEMS microphone diaphragm when said MEMS device is fabricated to be a MEMS microphone.

4. The integrated MEMS device as claimed in claim 1, wherein said bottom without slots can function as a MEMS pressure sensor.

5. The integrated MEMS device as claimed in claim 1, wherein said (Re-Distribution layer (RDL) is used to connect MEMS signal to circuit input terminals so as to preserve integrity of said CMOS scribe seal without breaking the CMOS circuit seal rings and thus insure the CMOS reliability.

6. The integrated MEMS device as claimed in claim 1, wherein said dimple is formed with hole in said first Nitride layer and said second Nitride layer.

7. The integrated MEMS device as claimed in claim 1, wherein said bonding wafer layer further forms a plurality of hole as particle filters.

8. The integrated MEMS device as claimed in claim 3, wherein said oxide area of said CMOS circuit layer in said MEMS area is etched to stop at said gap control layer for adjusting the distance between said diaphragms and said top plates so as to change capacitance between said diaphragms and said top plates.

9. The integrated MEMS device as claimed in claim 1, wherein an interface area of said MEMS and said CMOS circuit layer is immersed in and surrounded by a scribe seal ring for protecting CMOS ASIC circuit reliability from external environmental impurity.

10. The integrated MEMS device as claimed in claim 9, wherein said CMOS ASIC circuits are built in between two scribe seal rings, one interfaces with said MEMS structure, the other interfaces with scribe line for die saw.

11. The integrated MEMS device as claimed in claim 1, wherein said Large Back Chamber Area (LBCA) is formed in CMOS substrate under said CMOS transistor so as to increase the sensitivity of said MEMS device.

12. The integrated MEMS device as claimed in claim 1, wherein said back chamber is formed by wafer bonding technique at the CMOS substrate, so that Wafer Level Package (WLP) is realized.

13. The integrated MEMS device as claimed in claim 10, wherein said wafer bonding materials are set so that laser die saw is realized.

14. The integrated MEMS device as claimed in claim 1, wherein a flip chip bumping WLP (Wafer Level Package) methodology is realized in MEMS devices for cost reduction.

15. The integrated MEMS device as claimed in claim 1, wherein design rules when using eutectic wafer bonding technology are set so that laser die saw is realized.

16. The integrated MEMS device as claimed in claim 1, wherein CMOS ASIC scribe line area is used as part of wafer bonding area.

17. The integrated MEMS device as claimed in claim 16, wherein said CMOS ASIC scribe line area is used for vertical mechanical support and forming vertical sidewalls of said back chamber.
